(19) United States
(12) Patent Application Publication
(10) Pub. No.: US 2026/0372060 A1
(43) Pub. Date: Nov. 19, 2026

(54) SEMICONDUCTOR STRUCTURE INCLUDING BONDING CONDUCTOR HAVING PROTRUDING PORTION

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 19/755,753

(22) Filed: Jul. 27, 2026

Related U.S. Application Data
(63) Continuation of application No. 18/803,581, filed on Aug. 13, 2024.

(51) Int. Cl. H10W 20/43; H10W 72/90; H10W 90/00

(52) U.S. Cl. CPC H10W 20/43; H10W 72/9415; H10W 72/942; H10W 90/00; H10W 90/701; H10W 90/792

(57) ABSTRACT

A semiconductor structure including a semiconductor substrate, an interconnect structure and a bonding structure is provided. The interconnect structure is disposed on the semiconductor substrate. The interconnect structure includes an interconnect wiring distributed on a top surface of the interconnect structure. The bonding structure is disposed on and electrically connected to the interconnect structure. The bonding structure includes a bonding dielectric structure and a bonding conductor. The bonding dielectric structure is disposed on the top surface of the interconnect structure and covers the interconnect wiring. The bonding conductor is embedded in the bonding dielectric structure, wherein the bonding conductor lands on the top surface of the interconnect wiring and a first sidewall of the interconnect wiring.

### CROSS-REFERENCE TO RELATED APPLICATION

This application is a continuation application of and claims the priority benefit of a prior application Ser. No. 18/803,581, filed on Aug. 13, 2024 and now pending. The entirety of the above-mentioned patent applications is hereby incorporated by reference herein and made a part of this specification.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed and greater bandwidth, as well as lower power consumption and latency has grown recently, there has grown a need for smaller and more creative packaging techniques of semiconductor dies. Currently, System-on-Integrated-Circuit (SoIC) components are becoming increasingly popular for their multi-functions and compactness. However, there are challenges related to the reliability of the SoIC components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a cross-sectional view of a semiconductor structure of a SoIC component in accordance with the first embodiment of the disclosure.

FIG. 2 schematically illustrates a cross-sectional view of a semiconductor structure in accordance with the second embodiment of the disclosure.

FIG. 3A through FIG. 3D schematically illustrate top views of the interconnect wiring and the bonding conductor in accordance with an embodiment of the disclosure.

FIG. 4 schematically illustrates a cross-sectional view of a semiconductor structure in accordance with the third embodiment of the disclosure.

FIG. 5A through FIG. 5D schematically illustrate top views of the interconnect wiring and the bonding conductor in accordance with other embodiment of the disclosure.

FIG. 6A through FIG. 6D schematically illustrate top views of the interconnect wiring and the bonding conductor in accordance with another embodiment of the disclosure.

FIG. 7A through FIG. 7D schematically illustrate top views of the interconnect wiring and the bonding conductor in accordance with an alternative embodiment of the disclosure.

FIG. 8 schematically illustrates a cross-sectional view of a semiconductor structure in accordance with the fourth embodiment of the disclosure.

FIG. 9 schematically illustrates a cross-sectional view of a semiconductor structure in accordance with the fifth embodiment of the disclosure.

FIG. 10 schematically illustrates a cross-sectional view of a semiconductor structure in accordance with the sixth embodiment of the disclosure.

FIG. 11 schematically illustrates a cross-sectional view of a semiconductor structure in accordance with the seventh embodiment of the disclosure.

FIG. 12 schematically illustrates a cross-sectional view of a semiconductor structure in accordance with the eighth embodiment of the disclosure.

FIG. 13 schematically illustrates a cross-sectional view of a semiconductor structure in accordance with the nineth embodiment of the disclosure.

FIG. 14 schematically illustrates a cross-sectional view of a semiconductor structure in accordance with the tenth embodiment of the disclosure.

FIG. 15 schematically illustrates a cross-sectional view of a semiconductor structure in accordance with the eleventh embodiment of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

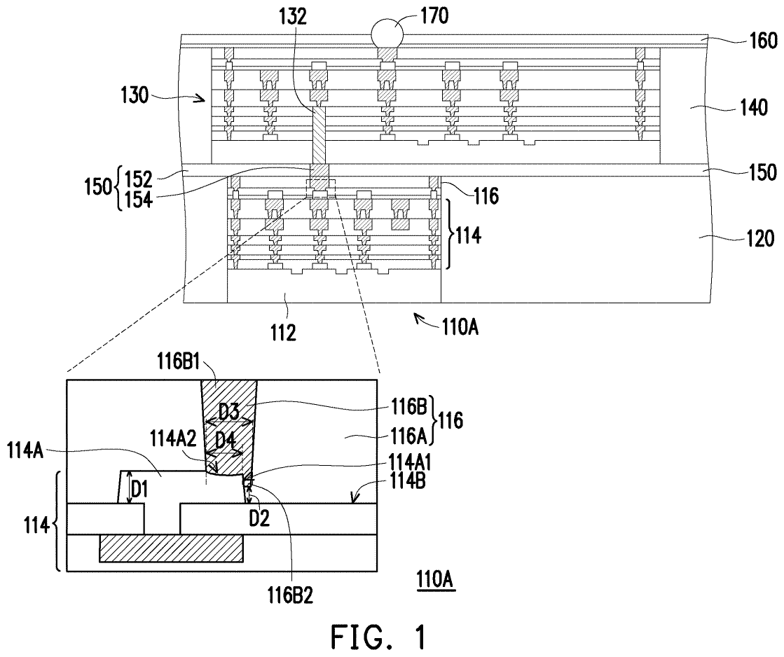

FIG. 1 schematically illustrates a cross-sectional view of a semiconductor structure of a SoIC component in accordance with the first embodiment of the disclosure.

Referring to the upper portion of FIG. 1, an SoIC component 100 is illustrated. The SoIC component 100 includes a semiconductor structure 110A, an insulating encapsulant 120, a semiconductor die 130, an insulating encapsulant 140, a bonding structure 150, a redistribution circuit structure 160 and a conductive terminals 170. The semiconductor structure 110A is laterally encapsulated by the insulating encapsulant 120, wherein the top surface of the semiconductor structure 110A substantially levels with the top surface of the insulating encapsulant 120, and the bottom surface of the semiconductor structure 110A substantially levels with the bottom surface of the insulating encapsulant 120. The insulating encapsulant 120 may be a gap filling dielectric material (e.g., tetraethoxysilane (TEOS) formed oxide material or other suitable dielectric material) formed by a deposition process (e.g., a chemical vapor deposition, a physical vapor deposition or other suitable deposition process) followed by a planarization process (e.g., a mechanical grinding process, a chemical mechanical polishing process, combination thereof or other suitable removal process). Alternatively, the insulating encapsulant 120 may be a molding compound formed by a mold injection process or other suitable process. The semiconductor die 130 is laterally encapsulated by the insulating encapsulant 140, wherein the top surface of the semiconductor die 130 substantially levels with the top surface of the insulating encapsulant 140, and the bottom surface of the semiconductor die 130 substantially levels with the bottom surface of the insulating encapsulant 140. The bonding structure 150 is disposed on the bottom surface of the semiconductor die 130 and the bottom surface of the insulating encapsulant 140, and the bonding structure 150 is electrically connected to the semiconductor die 130. For example, the bonding structure 150 is electrically connected to a through semiconductor via (TSV) 132 in the semiconductor die 130. The semiconductor die 130 is electrically connected to the semiconductor structure 110A through the bonding structure 150. The redistribution circuit structure 160 is disposed on and electrically connected to the semiconductor die 130, and the conductive terminals 170 is disposed on and electrically connected to the redistribution circuit structure 160. In other words, the conductive terminals 170 is electrically connected to the semiconductor die 130 through the redistribution circuit structure 160.

As illustrated in the upper portion of FIG. 1, the sidewalls of the insulating encapsulant 120 substantially align with the sidewalls of the insulating encapsulant 140, the sidewalls of the bonding structure 150 and the sidewalls of the redistribution circuit structure 160. The insulating encapsulant 120 is spaced apart from the insulating encapsulant 140 by the bonding structure 150. The bonding structure 150 may include a bonding dielectric structure 152 and a bonding conductor 154 embedded in the bonding dielectric structure 152. In some embodiments, the bonding dielectric structure 152 is a single-layered dielectric structure. In some alternative embodiments, the bonding dielectric structure 152 is a multi-layered structure including stacked dielectric layers. Furthermore, the bonding conductor 154 may be or include a bonding conductive via embedded in the bonding dielectric structure 152.

In some alternative embodiments, not illustrated in figures, the insulating encapsulant 140 is omitted. In other words, the sidewalls of the semiconductor die 130 may substantially align with the sidewalls of the insulating encapsulant 120, the sidewalls of the bonding structure 150 and the sidewalls of the redistribution circuit structure 160.

In the first embodiment of the disclosure, the semiconductor structure 110A includes a semiconductor substrate 112, an interconnect structure 114 and a bonding structure 116. Here, the above-mentioned semiconductor substrate 112 and the interconnect structure 114 are referred as to a semiconductor die. The interconnect structure 114 is disposed on the semiconductor substrate 110, as illustrated in the upper portion of FIG. 1. The interconnect structure 114 includes an interconnect wiring 114A distributed on a top surface 114B of the interconnect structure 114. The semiconductor substrate 112 may be a silicon substrate including active components (e.g., transistors or the like) and passive components (e.g., resistors, capacitors, inductors, or the like) formed therein. The active components and passive components are formed in the semiconductor substrate 112 through front end of line (FEOL) fabrication processes of semiconductor wafers. The interconnect structure 114 may include multi-layered interconnect wirings (e.g., copper interconnect wirings) and multi-layered dielectric layers stacked alternately, wherein the interconnect wirings of the interconnect structure 114 are electrically connected to the active components and/or the passive components in the semiconductor substrate 112. The interconnect structure 114 is formed through back end of line (BEOL) fabrication processes of semiconductor wafers. The topmost interconnect wiring 114A may be or include conductive pads. In the present embodiment shown in FIG. 1, the interconnect wiring 114A is an aluminum interconnect wiring or a copper doped aluminum pad.

The bonding structure 116 is disposed on and electrically connected to the interconnect structure 114. The bonding structure 116 includes a bonding dielectric structure 116A and a bonding conductor 116B. The bonding dielectric structure 116A is disposed on the top surface 114B of the interconnect structure 114 and covers the interconnect wiring 114A of the interconnect structure 114. The bonding conductor 116B of the bonding structure 116 is embedded in the bonding dielectric structure 116A of the bonding structure 116, wherein the bonding conductor 116B lands on the top surface 114A2 of the interconnect wiring 114A and a first sidewall 114A1 of the interconnect wiring 114A. As illustrated in FIG. 1, the bonding conductor 116B is disposed on and physically in contact with the top surface 114A2 of the interconnect wiring 114A and the first sidewall 114A1 of the interconnect wiring 114A. The material of the bonding dielectric structure 116A may be or include silicon oxide, silicon nitride, silicon oxy-nitride, or other suitable inorganic dielectric materials. The material of the bonding conductor 116B may be or include copper or other suitable conductive materials.

As illustrated in FIG. 1, the bonding conductor 116B in the semiconductor structure 110A includes a body portion 116B1 and a first protruding portion 116B2, the body portion 116B1 is embedded in the bonding dielectric structure 116A, the first protruding portion 116B2 is embedded in the bonding dielectric structure 116A, and the protruding portion 116B2 extends from the bottom of the body portion 116B1 downwardly so as to cover the upper part of the first sidewall 114A1 of the interconnect wiring 114A. In other words, the protruding portion 116B2 laterally covers and is physically in contact with the first sidewall 114A1 of the interconnect wiring 114A. Furthermore, the first protruding portion 116B2 is spaced apart from the top surface 114B of the interconnect structure 114 by a distance D2.

The bonding conductor 116B in the semiconductor structure 110A is physically in contact with and is bonded to the bonding conductor 154 of the bonding structure 150. The bonding interface between the bonding structure 116 and the bonding structure 150 includes metal-to-metal bonding interface and dielectric-to-dielectric bonding interface, wherein the metal-to-metal bonding interface is between the bonding conductor 116B and the bonding conductor 154, and the dielectric-to-dielectric bonding interface is between the bonding dielectric structure 116A and the bonding dielectric structure 152 as well as between the insulating encapsulant 120 and the bonding dielectric structure 152.

As illustrated in FIG. 1, the thickness D1 of the interconnect wiring 114A may range from about 0.1 micrometer to about 100 micrometers, the remaining thickness D2 of the bonding dielectric structure 116A underlying the first protruding portion 116B2 may range from about 0.1 micrometer to about 100 micrometers, the bottom dimension D3 of the body portion 116B1 may range from about 0.1 micrometer to about 100 micrometers, and the lateral dimension D4 of a recessed portion of the top surface 114A2 covered by the body portion 116B1 may range from about 0.1 micrometer to about 100 micrometers. The thickness D1 of the interconnect wiring 114A is greater than the remaining thickness D2 of the bonding dielectric structure 116A, and the bottom dimension D3 of the body portion 116B1 is greater than the lateral dimension D4 of the recessed portion of the top surface 114A2 covered by the body portion 116B1.

In some embodiments, the thickness D1 of the interconnect wiring 114A may be about 28 micrometers, the remaining thickness D2 of the bonding dielectric structure 116A may be greater than about 0.01 micrometer. The difference between the thickness D1 of the interconnect wiring 114A and the remaining thickness D2 of the bonding dielectric structure 116A may be greater than about 1 angstrom. The ratio of the remaining thickness D2 of the bonding dielectric structure 116A to the thickness D1 of the interconnect wiring 114A may range from about 0.01 to about 0.99, preferably about 0.05. The difference between the bottom dimension D3 of the body portion 116B1 and the lateral dimension D4 of the recessed portion of the top surface 114A2 (i.e. the maximum lateral dimension or the top dimension of the first protruding portion 116B2) may be greater than about 0.1 micrometer. The ratio of the lateral dimension D4 of the portion of the top surface 114A2 to the bottom dimension D3 of the body portion 116B1 may range from about 0.11 to about 0.99, preferably from about 0.11 to about 0.70.

As illustrated in FIG. 1, an intentional shift (i.e., the offset (D4−D3)) between the body portion 116B1 and the interconnect wiring 114A is obtained based on design rule such that the contact area between the body portion 116B1 and the interconnect wiring 114A can increase. In other words, since the body portion 116B1 is physically in contact with the recessed portion of the top surface 114A2 and the first sidewall 114A1 of the interconnect wiring 114A, the contact area between the body portion 116B1 and the interconnect wiring 114A can increase without significantly increasing the overall layout area of the body portion 116B1 and the interconnect wiring 114A. Accordingly, the contact resistance between the body portion 116B1 and the interconnect wiring 114A can be minimized due to the increased contact area between the body portion 116B1 and the interconnect wiring 114A.

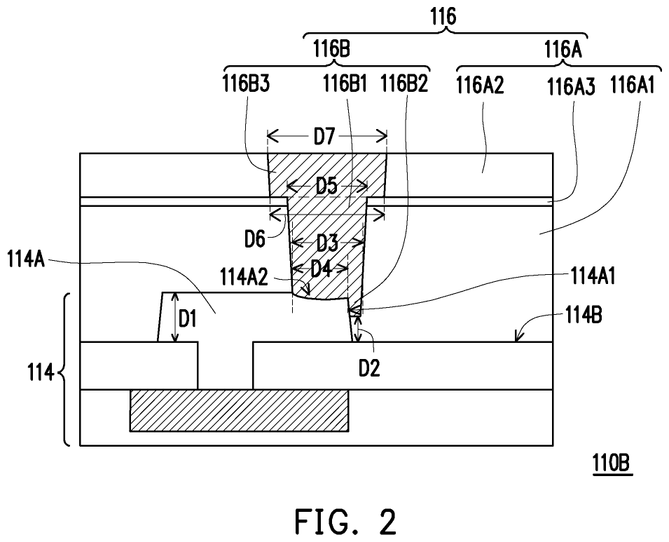

FIG. 2 schematically illustrates a cross-sectional view of a semiconductor structure in accordance with the second embodiment of the disclosure.

Referring to FIG. 1 and FIG. 2, the semiconductor structure 110B illustrated in FIG. 2 is similar to the semiconductor structure 110A illustrated in FIG. 1 except that the bonding dielectric structure 116A of the bonding structure 116 illustrated in FIG. 2 is a multi-layered dielectric structure. In the second embodiment of the present disclosure, the bonding dielectric structure 116A includes a first dielectric layer 116A1, a second dielectric layer 116A2 and an etch stop layer 116A3. The first dielectric layer 116A1 is disposed on the top surface 114B of the interconnect structure 114, and the first dielectric layer 116A1 covers the interconnect wiring 114A. The second dielectric layer 116A2 is disposed over the first dielectric layer 116A1. The etch stop layer 116A3 is disposed between the first dielectric layer 116A1 and the second dielectric layer 116A2. The bonding conductor 116 is embedded in and penetrates through the first dielectric layer 116A1, the etch stop layer 116A3 and the second dielectric layer 116A2.

Due to the etch stop layer 116A3 formed between the first dielectric layer 116A1 and the second dielectric layer 116A2, the bonding conductor 116B includes a bottom portion 116B1, a first protruding portion 116B2 and a top portion 116B3. The top portion 116B3 is wider than bottom portion 116B1. As illustrated in FIG. 2, the bottom portion 116B1 of the bonding conductor 116B is embedded in and is physically in contact with the first dielectric layer 116A1 and the etch stop layer 116A3, the first protruding portion 116B2 of the bonding conductor 116B is embedded in and is physically in contact with the first dielectric layer 116A1, and the top portion 116B3 of the bonding conductor 116B is embedded in and is physically in contact with the second dielectric layer 116A2. The top portion 116B3 covers the top surface of the etch stop layer 116A3. The first protruding portion 116B2 extends from the bottom of the bottom portion 116B1 to cover the first sidewall 114A1 of the interconnect wiring 114A.

In some embodiments, the bottom portion 116B1 includes a first bottom dimension D3 and a first top dimension D5, the top portion 116B3 includes a second bottom dimension D6 and a second bottom dimension D7, the first top dimension D5 of the bottom portion 116B1 is greater than the first bottom dimension D3 of the bottom portion 116B1, the second top dimension D7 of the top portion 116B3 is greater than the second bottom dimension D6 of the top portion 116B3, and the second bottom dimension D6 of the top portion 116B3 is greater than the first top dimension D5 of the bottom portion 116B1.

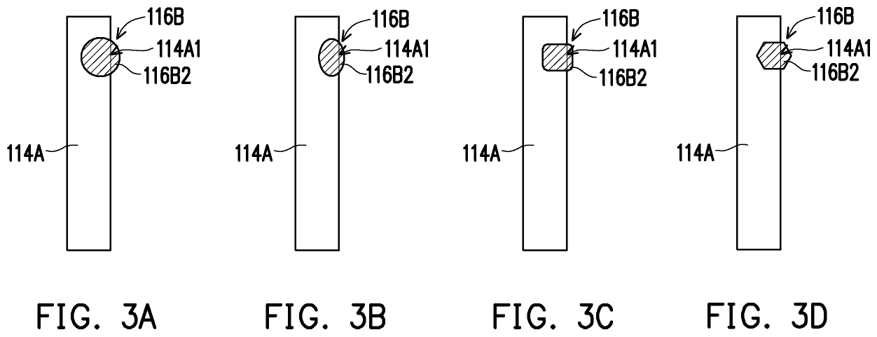

FIG. 3A through FIG. 3D schematically illustrate top views of the interconnect wiring and the bonding conductor in accordance with an embodiment of the disclosure.

Referring to FIG. 3A through FIG. 3D, when viewing from the top of the bonding conductor 116B and the interconnect wiring 114A, the bonding conductor 116B lands on and is overlapped with the interconnect wiring 114A, and the first protruding portion 116B2 of the bonding conductor 116B leans against the first sidewall 114A1 of the interconnect wiring 114A. When viewing from the top of the bonding conductor 116B and the interconnect wiring 114A, the bonding conductor 116B has a circular profile (shown in FIG. 3A), an oval profile (shown in FIG. 3B), a rectangular or square profile with or without rounded corners (shown in FIG. 3C) or a hexagonal profile (shown in FIG. 3D).

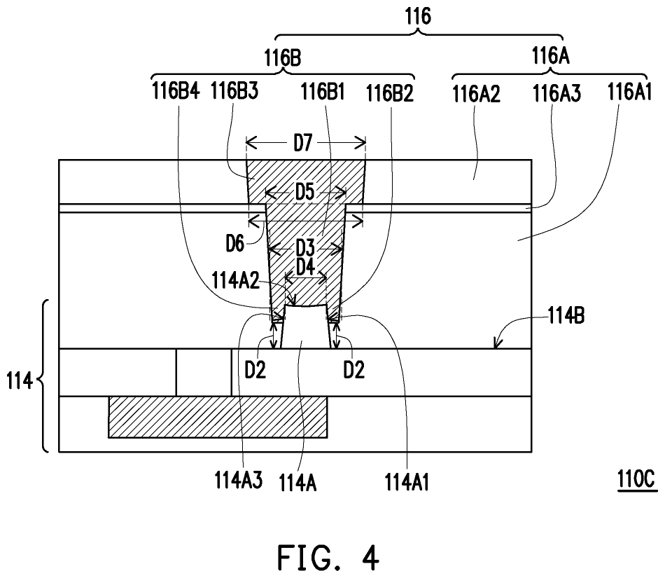

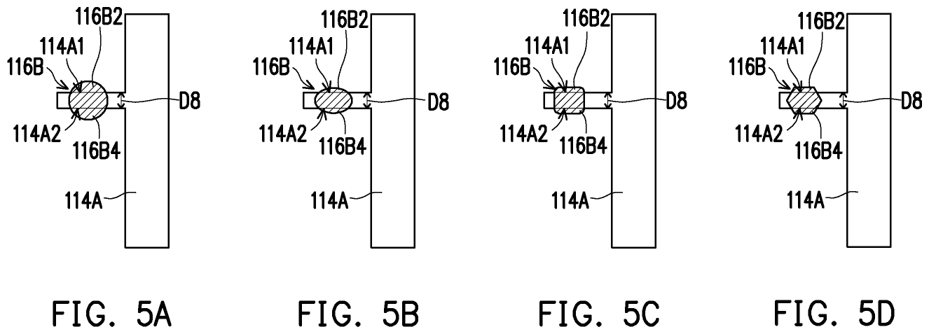

FIG. 4 schematically illustrates a cross-sectional view of a semiconductor structure in accordance with the third embodiment of the disclosure. FIG. 5A through FIG. 5D schematically illustrate top views of the interconnect wiring and the bonding conductor in accordance with other embodiment of the disclosure.

Referring to FIG. 4, in the third embodiment of the disclosure, the semiconductor structure 110C includes a semiconductor substrate 112, an interconnect structure 114 and a bonding structure 116. Here, the above-mentioned semiconductor substrate 112 and the interconnect structure 114 are referred as to a semiconductor die. The interconnect structure 114 is disposed on the semiconductor substrate 110, as illustrated in the upper portion of FIG. 1. The interconnect structure 114 includes an interconnect wiring 114A distributed on a top surface 114B of the interconnect structure 114. The semiconductor substrate 112 may be a silicon substrate including active components (e.g., transistors or the like) and passive components (e.g., resistors, capacitors, inductors, or the like) formed therein. The active components and passive components are formed in the semiconductor substrate 112 through front end of line (FEOL) fabrication processes of semiconductor wafers. The interconnect structure 114 may include multi-layered interconnect wirings (e.g., copper interconnect wirings) and multi-layered dielectric layers stacked alternately, wherein the interconnect wirings of the interconnect structure 114 are electrically connected to the active components and/or the passive components in the semiconductor substrate 112. The interconnect structure 114 is formed through back end of line (BEOL) fabrication processes of semiconductor wafers. The topmost interconnect wiring 114A may be or include conductive pads. In the present embodiment shown in FIG. 1, the interconnect wiring 114A is an aluminum interconnect wiring or a copper doped aluminum pad.

The bonding structure 116 is disposed on and electrically connected to the interconnect structure 114. The bonding structure 116 includes a bonding dielectric structure 116A and a bonding conductor 116B. The bonding dielectric structure 116A is disposed on the top surface 114B of the interconnect structure 114 and covers the interconnect wiring 114A of the interconnect structure 114. The bonding conductor 116B of the bonding structure 116 is embedded in the bonding dielectric structure 116A of the bonding structure 116, wherein the bonding conductor 116B lands on a first sidewall 114A1 of the interconnect wiring 114A, the top surface 114A2 of the interconnect wiring 114A and a second sidewall 114A3 of the interconnect wiring 114A. As illustrated in FIG. 4, the bonding conductor 116B is disposed on and physically in contact with the top surface 114A2 of the interconnect wiring 114A, the first sidewall 114A1 of the interconnect wiring 114A and the second sidewall 114A3 of the interconnect wiring 114A. The material of the bonding dielectric structure 116A may be or include silicon oxide, silicon nitride, silicon oxy-nitride, or other suitable inorganic dielectric materials. The material of the bonding conductor 116B may be or include copper or other suitable conductive materials.

As illustrated in FIG. 4, the bonding conductor 116B includes a bottom portion 116B1, a first protruding portion 116B2, a top portion 116B3 and a second protruding portion 116B4. The top portion 116B3 is wider than bottom portion 116B1. The bottom portion 116B1 of the bonding conductor 116B is embedded in and is physically in contact with the first dielectric layer 116A1 and the etch stop layer 116A3, the first protruding portion 116B2 of the bonding conductor 116B is embedded in and is physically in contact with the first dielectric layer 116A1, the top portion 116B3 of the bonding conductor 116B is embedded in and is physically in contact with the second dielectric layer 116A2, and the second protruding portion 116B4 of the bonding conductor 116B is embedded in and is physically in contact with the first dielectric layer 116A1. The second sidewall 114A3 is opposite to the first sidewall 114A1. The first protruding portion 116B2 and the second protruding portion 116B4 are located at opposite sides of the interconnect wiring 114A. The top portion 116B3 covers the top surface of the etch stop layer 116A3. The first protruding portion 116B2 extends from the bottom of the bottom portion 116B1 downwardly so as to cover the upper part of the first sidewall 114A1 of the interconnect wiring 114A. The second protruding portion 116B4 extends from the bottom of the bottom portion 116B1 downwardly so as to cover the upper part of the second sidewall 114A3 of the interconnect wiring 114A. Furthermore, both the first protruding portion 116B2 and the second protruding portion 116B4 are spaced apart from the top surface 114B of the interconnect structure 114.

As illustrated in FIG. 4, the thickness D1 of the interconnect wiring 114A may range from about 0.1 micrometer to about 100 micrometers, the remaining thickness D2 of the bonding dielectric structure 116A underlying the first protruding portion 116B2 or and the second protruding portion 116B4 may range from about 0.1 micrometer to about 100 micrometers, the bottom dimension D3 of the body portion 116B1 may range from about 0.1 micrometer to about 100 micrometers, and the lateral dimension D4 of the top surface 114A2 covered by the body portion 116B1 may range from about 0.1 micrometer to about 100 micrometers. The thickness D1 of the interconnect wiring 114A is greater than the remaining thickness D2 of the bonding dielectric structure 116A, and the bottom dimension D3 of the body portion 116B1 is greater than the lateral dimension D4 of the top surface 114A2 covered by the body portion 116B1.

In some embodiments, the thickness D1 of the interconnect wiring 114A may be about 28 micrometers, the remaining thickness D2 of the bonding dielectric structure 116A may be greater than about 0.01 micrometer. The difference between the thickness D1 of the interconnect wiring 114A and the remaining thickness D2 of the bonding dielectric structure 116A may be greater than about 1 angstrom. The ratio of the remaining thickness D2 of the bonding dielectric structure 116A to the thickness D1 of the interconnect wiring 114A may range from about 0.01 to about 0.99, preferably about 0.05. The half of the difference between the bottom dimension D3 of the body portion 116B1 and the lateral dimension D4 of the top surface 114A2 (i.e. the maximum lateral dimension or the top dimension of the first protruding portion 116B2 or the second protruding portion 116B4) may be greater than about 0.1 micrometer. The ratio of the lateral dimension D4 of the portion of the top surface 114A2 to the bottom dimension D3 of the body portion 116B1 may range from about 0.11 to about 0.99, preferably from about 0.11 to about 0.70.

As illustrated in FIG. 4, an intentional overlay design between the body portion 116B1 and the interconnect wiring 114A is obtained based on design rule such that the contact area between the body portion 116B1 and the interconnect wiring 114A can increase. In other words, since the body portion 116B1 is physically in contact with the top surface 114A2, the first sidewall 114A1 and the second sidewall 114A3 of the interconnect wiring 114A, the contact area between the body portion 116B1 and the interconnect wiring 114A can increase without significantly increasing the overall layout area of the body portion 116B1 and the interconnect wiring 114A. Accordingly, the contact resistance between the body portion 116B1 and the interconnect wiring 114A can be minimized due to the increased contact area between the body portion 116B1 and the interconnect wiring 114A.

As illustrated in FIG. 4, the bonding dielectric structure 116A is a multi-layered dielectric structure, and the bonding conductor 116B with two protruding portions 116B2 and 116B4 are embedded in the bonding dielectric structure 116A. In some alternative embodiments, not illustrated in Figures, the bonding dielectric structure is a single-layered dielectric structure similar to the bonding dielectric structure shown in FIG. 1, and the bonding conductor with two protruding portions are embedded in the single layered bonding dielectric structure.

Referring to FIG. 5A through FIG. 5D, when viewing from the top of the bonding conductor 116B and the interconnect wiring 114A, the bonding conductor 116B lands on and is overlapped with a branch portion of the interconnect wiring 114A, the first protruding portion 116B2 of the bonding conductor 116B leans against the first sidewall 114A1 of the branch portion of the interconnect wiring 114A, and the second protruding portion 116B4 of the bonding conductor 116B leans against the second sidewall 114A2 of the branch portion of the interconnect wiring 114A. When viewing from the top of the bonding conductor 116B and the interconnect wiring 114A, the bonding conductor 116B has a circular profile (shown in FIG. 5A), an oval profile (shown in FIG. 5B), a rectangular or square profile with or without rounded corners (shown in FIG. 5C) or a hexagonal profile (shown in FIG. 5D). For example, the linewidth D8 of the branch portion of the interconnect wiring 114A is greater than 0.01 micrometer. In some embodiments, the linewidth D8 of the branch portion of the interconnect wiring 114A is about 50% of the bottom dimension D3 of the body portion 116B1 (shown in FIG. 4).

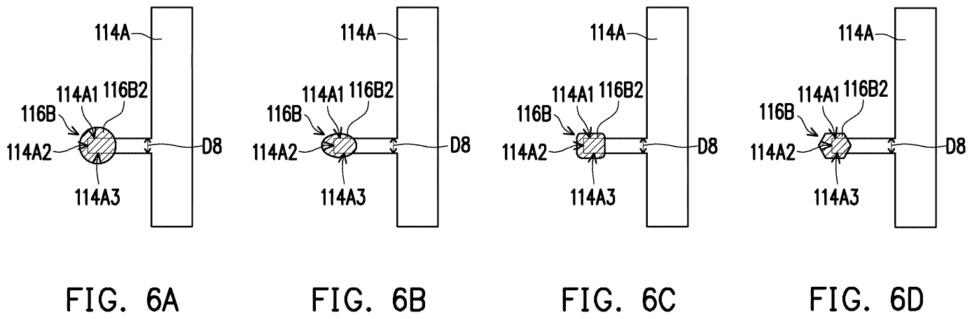

FIG. 6A through FIG. 6D schematically illustrate top views of the interconnect wiring and the bonding conductor in accordance with another embodiment of the disclosure.

Referring to FIG. 6A through FIG. 6D, when viewing from the top of the bonding conductor 116B and the interconnect wiring 114A, the bonding conductor 116B lands on and is overlapped with an end of the interconnect wiring 114A, the protruding portion 116B2 of the bonding conductor 116B leans against the first sidewall 114A1 of the branch portion of the interconnect wiring 114A, the second sidewall 114A2 of the branch portion of the interconnect wiring 114A and the third sidewall 114A3 of the branch portion of the interconnect wiring 114A. The second sidewall 114A2 abuts the first sidewall 114A1 and the third sidewall 114A3, and the third sidewall 114A3 is opposite to the first sidewall 114A1. The bonding conductor 116B lands on two adjacent corners of the branch portion of the interconnect wiring 114A. When viewing from the top of the bonding conductor 116B and the interconnect wiring 114A, the bonding conductor 116B has a circular profile (shown in FIG. 6A), an oval profile (shown in FIG. 6B), a rectangular or square profile with or without rounded corners (shown in FIG. 6C) or a hexagonal profile (shown in FIG. 6D). For example, the linewidth D8 of the branch portion of the interconnect wiring 114A is greater than 0.01 micrometer. In some embodiments, the linewidth D8 of the branch portion of the interconnect wiring 114A is about 50% of the bottom dimension D3 of the body portion 116B1 (shown in FIG. 4).

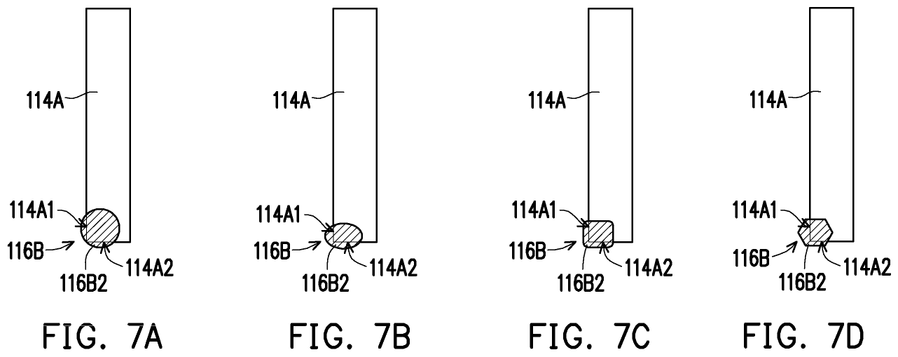

FIG. 7A through FIG. 7D schematically illustrate top views of the interconnect wiring and the bonding conductor in accordance with an alternative embodiment of the disclosure.

Referring to FIG. 7A through FIG. 7D, when viewing from the top of the bonding conductor 116B and the interconnect wiring 114A, the bonding conductor 116B lands on and is overlapped with a corner of the interconnect wiring 114A, the protruding portion 116B2 of the bonding conductor 116B leans against the first sidewall 114A1 of the interconnect wiring 114A and the second sidewall 114A2 of the interconnect wiring 114A. The second sidewall 114A2 abuts the first sidewall 114A1, and the second sidewall 114A2 and the first sidewall 114A1 are intersected at the corner. When viewing from the top of the bonding conductor 116B and the interconnect wiring 114A, the bonding conductor 116B has a circular profile (shown in FIG. 7A), an oval profile (shown in FIG. 7B), a rectangular or square profile with or without rounded corners (shown in FIG. 7C) or a hexagonal profile (shown in FIG. 7D).

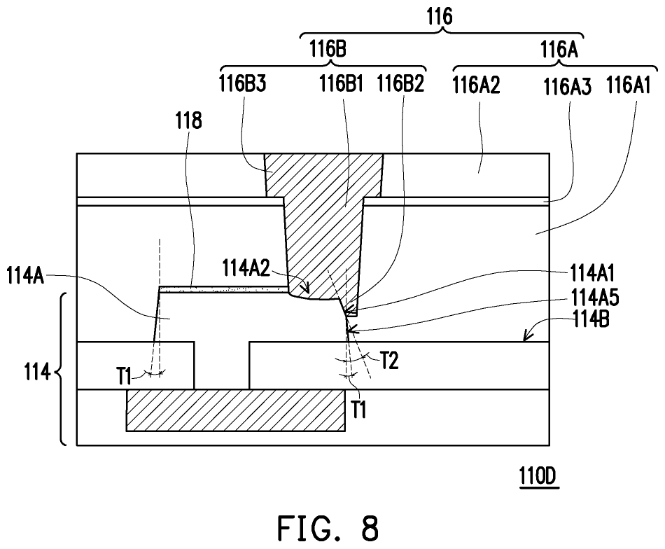

FIG. 8 schematically illustrates a cross-sectional view of a semiconductor structure in accordance with the fourth embodiment of the disclosure.

Referring to FIG. 2 and FIG. 8, the semiconductor structure 110D illustrated FIG. 8 is similar to the semiconductor structure 110B illustrated in FIG. 2 except that the bonding conductor 116B lands on the top surface 114A2 of the interconnect wiring 114A and a first tapered sidewall 114A1 of the interconnect wiring 114A, the first dielectric layer 116A1 of the bonding dielectric structure 116A is physically in contact with a second tapered sidewall 114A5 of the interconnect wiring 114A, the first tapered sidewall 114A1 of the interconnect wiring 114A extends from the top surface 114A2 of the interconnect wiring 114A to the second tapered sidewall 114A5 of the interconnect wiring 114A, and the second tapered sidewall 114A5 of the interconnect wiring 114A is steeper than the first tapered sidewall 114A1 of the interconnect wiring 114A. For example, an included angle T1 between the normal line of the top surface 114B of the interconnect structure 114 and the second tapered sidewall 114A5 ranges from about 0.01 degree to about 80 degrees, an included angle T2 between the normal line of the top surface 114B of the interconnect structure 114 and the first tapered sidewall 114A1 ranges from about 0.01 degree to about 80 degrees, and the included angle T2 is greater than the included angle T1.

Furthermore, at least one barrier layer 118 may be optionally formed on the top surface 114A2 of the interconnect wiring 114A, and the at least one barrier layer 118 may be optionally formed between the top surface 114A2 of the interconnect wiring 114A and the first dielectric layer 116A1 of the bonding dielectric structure 116A. For example, the material of the at least one barrier layer 118 may be or include tungsten (W), titanium nitride (TiN), titanium (Ti), tantalum (Ta), tantalum nitride (TaN), combinations thereof or other suitable materials.

It is noted that the shape of the bonding conductor 116B as well as the overlay between the bonding conductor 116B and the interconnect wiring 114A illustrated in FIG. 3A through FIG. 3D, FIG. 5A through FIG. 5D, FIG. 6A through FIG. 6D and FIG. 7A through FIG. 7D may be applied to the fourth embodiment of the disclosure.

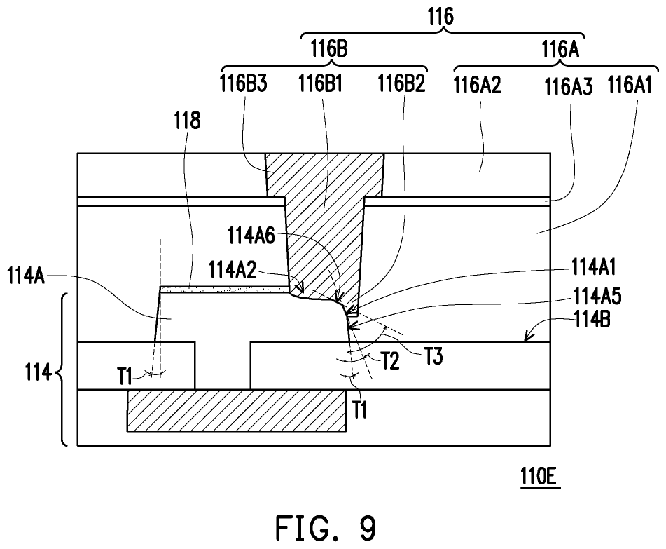

FIG. 9 schematically illustrates a cross-sectional view of a semiconductor structure in accordance with the fifth embodiment of the disclosure.

Referring to FIG. 2 and FIG. 9, the semiconductor structure 110E illustrated in FIG. 9 is similar to the semiconductor structure 110B illustrated in FIG. 2 except that the bonding conductor 116B lands on the top surface 114A2 of the interconnect wiring 114A, a first tapered sidewall 114A1 of the interconnect wiring 114A and a tapered surface 114A6 of the interconnect wiring 114A, the first dielectric layer 116A1 of the bonding dielectric structure 116A is physically in contact with a second tapered sidewall 114A5 of the interconnect wiring 114A. In the present embodiment, the tapered surface 114A6 of the interconnect wiring 114A extends from the top surface 114A2 of the interconnect wiring 114A to the first tapered sidewall 114A1 of the interconnect wiring 114A, and the first tapered sidewall 114A1 of the interconnect wiring 114A is steeper than the tapered surface 114A6 of the interconnect wiring 114A. For example, an included angle T1 between the normal line of the top surface 114B of the interconnect structure 114 and the second tapered sidewall 114A5 ranges from about 0.01 degree to about 80 degrees, an included angle T2 between the normal line of the top surface 114B of the interconnect structure 114 and the first tapered sidewall 114A1 ranges from about 0.01 degree to about 80 degrees, an included angle T3 between the normal line of the top surface 114B of the interconnect structure 114 and the tapered surface 114A6 ranges from about 0.01 degree to about 80 degrees, wherein the included angle T3 is greater than the included angle T2, and the included angle T2 is greater than the included angle T1.

Furthermore, at least one barrier layer 118 may be optionally formed on the top surface 114A2 of the interconnect wiring 114A, and the at least one barrier layer 118 may be optionally formed between the top surface 114A2 of the interconnect wiring 114A and the first dielectric layer 116A1 of the bonding dielectric structure 116A. For example, the material of the at least one barrier layer 118 may be or include tungsten (W), titanium nitride (TiN), titanium (Ti), tantalum (Ta), tantalum nitride (TaN), combinations thereof or other suitable materials.

It is noted that the shape of the bonding conductor 116B as well as the overlay between the bonding conductor 116B and the interconnect wiring 114A illustrated in FIG. 3A through FIG. 3D, FIG. 5A through FIG. 5D, FIG. 6A through FIG. 6D and FIG. 7A through FIG. 7D may be applied to the fifth embodiment of the disclosure.

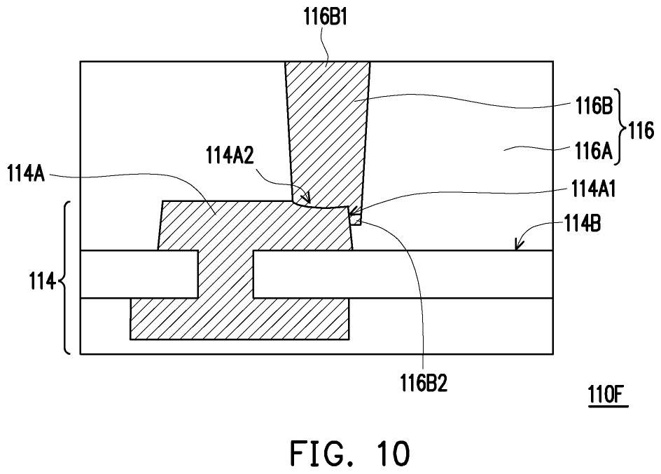

FIG. 10 schematically illustrates a cross-sectional view of a semiconductor structure in accordance with the sixth embodiment of the disclosure.

Referring to FIG. 1 and FIG. 10, the semiconductor structure 110F illustrated in FIG. 10 is similar to the semiconductor structure 110A illustrated in FIG. 1 except that the topmost interconnect wiring 114A of the interconnect structure 114 is a copper interconnect wiring or a copper pad.

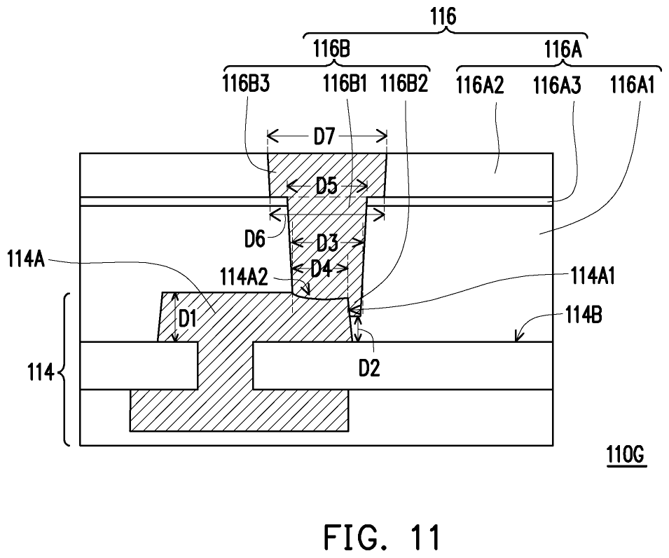

FIG. 11 schematically illustrates a cross-sectional view of a semiconductor structure in accordance with the seventh embodiment of the disclosure.

Referring to FIG. 2 and FIG. 11, the semiconductor structure 110G illustrated in FIG. 11 is similar to the semiconductor structure 110B illustrated in FIG. 2 except that the topmost interconnect wiring 114A of the interconnect structure 114 is a copper interconnect wiring or a copper pad.

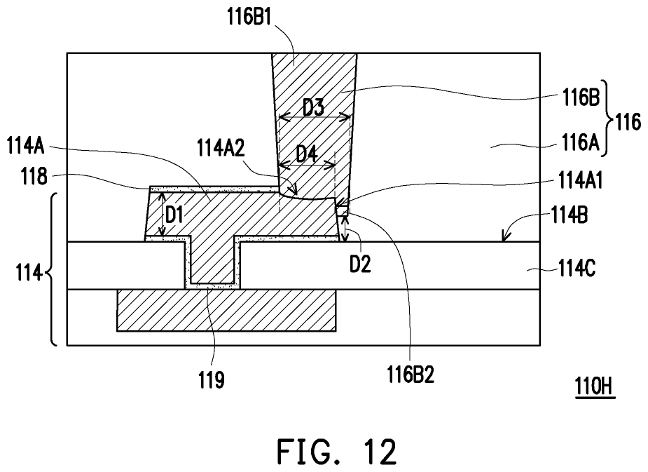

FIG. 12 schematically illustrates a cross-sectional view of a semiconductor structure in accordance with the eighth embodiment of the disclosure.

Referring to FIG. 1 and FIG. 12, the semiconductor structure 110H illustrated in FIG. 12 is similar to the semiconductor structure 110A illustrated in FIG. 1 except that the topmost interconnect wiring 114A of the interconnect structure 114 is a copper interconnect wiring or a copper pad, and a top barrier layer 118 and a bottom barrier layer 119 are formed to protect the interconnect wiring 114A. The top barrier layer 118 is formed to cover the top surface 114A2 of the interconnect wiring 114A, and the bottom barrier layer 119 is formed to cover the top surface 114B of the interconnect structure 114. The top barrier layer 118 is formed between the bonding dielectric structure 116A and the top surface 114A2 of the interconnect wiring 114A. The bottom barrier layer 119 is formed between a passivation layer 114C of the interconnect structure 114 and the interconnect wiring 114A. Furthermore, the material of the top barrier layer 118 and the bottom barrier layer 119 may be or include tungsten (W), titanium nitride (TiN), titanium (Ti), tantalum (Ta), tantalum nitride (TaN), combinations thereof or other suitable materials.

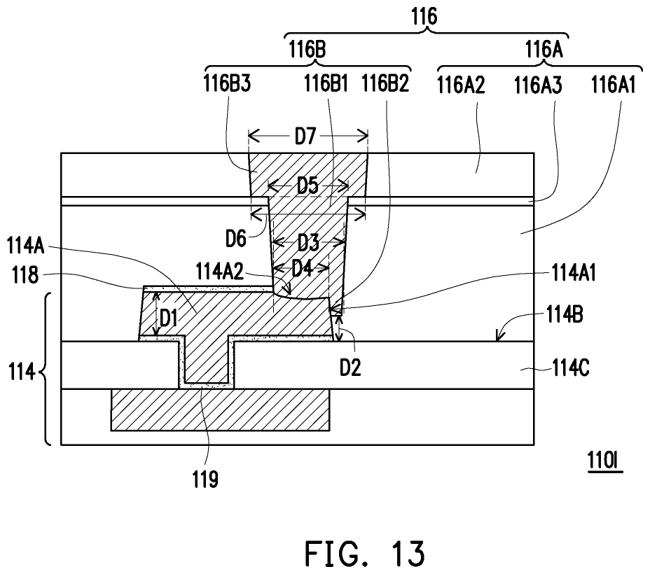

FIG. 13 schematically illustrates a cross-sectional view of a semiconductor structure in accordance with the nineth embodiment of the disclosure.

Referring to FIG. 2 and FIG. 13, the semiconductor structure 110I illustrated in FIG. 13 is similar to the semiconductor structure 110B illustrated in FIG. 2 except that the topmost interconnect wiring 114A of the interconnect structure 114 is a copper interconnect wiring or a copper pad, and a top barrier layer 118 and a bottom barrier layer 119 are formed to protect the interconnect wiring 114A. The top barrier layer 118 is formed to cover the top surface 114A2 of the interconnect wiring 114A, and the bottom barrier layer 119 is formed to cover the top surface 114B of the interconnect structure 114. The top barrier layer 118 is formed between the first dielectric layer 116A1 of the bonding dielectric structure 116A and the top surface 114A2 of the interconnect wiring 114A. The bottom barrier layer 119 is formed between a passivation layer 114C of the interconnect structure 114 and the interconnect wiring 114A. Furthermore, the material of the top barrier layer 118 and the bottom barrier layer 119 may be or include tungsten (W), titanium nitride (TiN), titanium (Ti), tantalum (Ta), tantalum nitride (TaN), combinations thereof or other suitable materials.

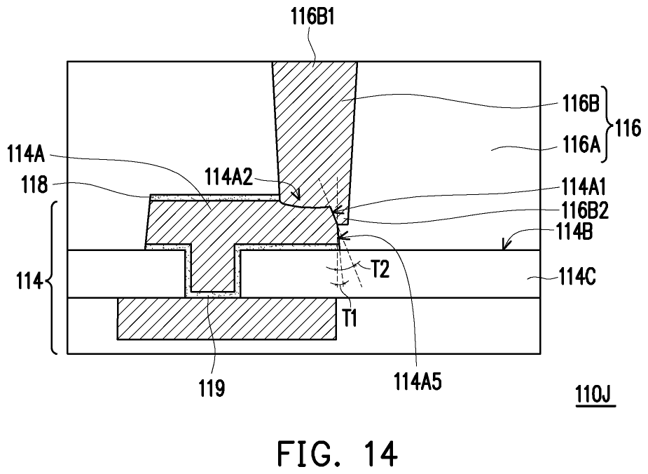

FIG. 14 schematically illustrates a cross-sectional view of a semiconductor structure in accordance with the tenth embodiment of the disclosure.

Referring to FIG. 8 and FIG. 14, the semiconductor structure 110J illustrated in FIG. 14 is similar to the semiconductor structure 110D illustrated in FIG. 8 except that the topmost interconnect wiring 114A of the interconnect structure 114 is a copper interconnect wiring or a copper pad, and a top barrier layer 118 and a bottom barrier layer 119 are formed to protect the interconnect wiring 114A. The top barrier layer 118 is formed to cover the top surface 114A2 of the interconnect wiring 114A, and the bottom barrier layer 119 is formed to cover the top surface 114B of the interconnect structure 114. The top barrier layer 118 is formed between the first dielectric layer 116A1 of the bonding dielectric structure 116A and the top surface 114A2 of the interconnect wiring 114A. The bottom barrier layer 119 is formed between a passivation layer 114C of the interconnect structure 114 and the interconnect wiring 114A. Furthermore, the material of the top barrier layer 118 and the bottom barrier layer 119 may be or include tungsten (W), titanium nitride (TiN), titanium (Ti), tantalum (Ta), tantalum nitride (TaN), combinations thereof or other suitable materials.

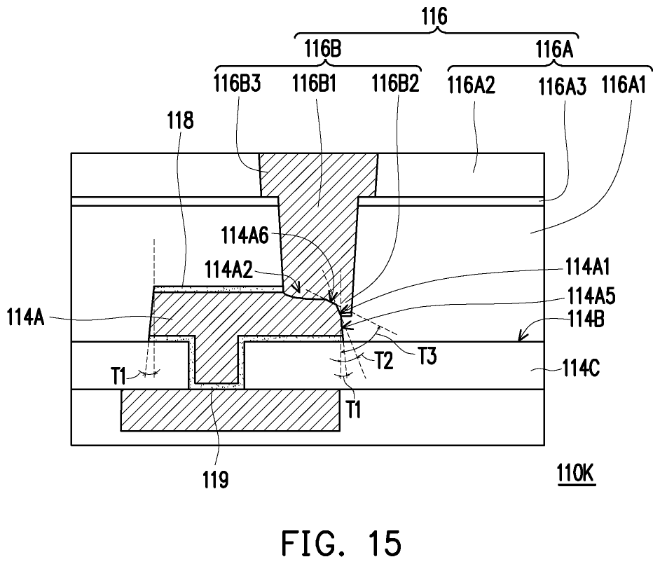

FIG. 15 schematically illustrates a cross-sectional view of a semiconductor structure in accordance with the eleventh embodiment of the disclosure.

Referring to FIG. 9 and FIG. 15, the semiconductor structure 110K illustrated in FIG. 15 is similar to the semiconductor structure 110E illustrated in FIG. 9 except that the topmost interconnect wiring 114A of the interconnect structure 114 is a copper interconnect wiring or a copper pad, and a top barrier layer 118 and a bottom barrier layer 119 are formed to protect the interconnect wiring 114A. The top barrier layer 118 is formed to cover the top surface 114A2 of the interconnect wiring 114A, and the bottom barrier layer 119 is formed to cover the top surface 114B of the interconnect structure 114. The top barrier layer 118 is formed between the first dielectric layer 116A1 of the bonding dielectric structure 116A and the top surface 114A2 of the interconnect wiring 114A. The bottom barrier layer 119 is formed between a passivation layer 114C of the interconnect structure 114 and the interconnect wiring 114A. Furthermore, the material of the top barrier layer 118 and the bottom barrier layer 119 may be or include tungsten (W), titanium nitride (TiN), titanium (Ti), tantalum (Ta), tantalum nitride (TaN), combinations thereof or other suitable materials.

In order to minimize the contact resistance between the bonding conductor and the interconnect wiring without significantly increasing the layout area of the bonding conductor and the interconnect wiring, the above-mentioned embodiments of the present disclosure utilize intentional overlay design between the body portion and the interconnect wiring to increase the contact surface between the bonding conductor and the interconnect wiring. The structure reduces under-etching and delamination defects, improving yield.

In accordance with some embodiments of the present disclosure, a semiconductor structure including a semiconductor substrate, an interconnect structure and a bonding structure is provided. The interconnect structure is disposed on the semiconductor substrate. The interconnect structure includes an interconnect wiring distributed on a top surface of the interconnect structure. The bonding structure is disposed on and electrically connected to the interconnect structure. The bonding structure includes a bonding dielectric structure and a bonding conductor. The bonding dielectric structure is disposed on the top surface of the interconnect structure and covers the interconnect wiring. The bonding conductor is embedded in the bonding dielectric structure, wherein the bonding conductor lands on the top surface of the interconnect wiring and a first sidewall of the interconnect wiring. In some embodiments, the bonding dielectric structure includes a first dielectric layer disposed on the top surface of the interconnect structure and covering the interconnect wiring; a second dielectric layer disposed over the first dielectric layer; and an etch stop layer disposed between the first dielectric layer and the second dielectric layer, wherein the bonding conductor penetrates through the first dielectric layer, the etch stop layer and the second dielectric layer. In some embodiments, the bonding conductor includes a bottom portion embedded in the first dielectric layer and the etch stop layer; a first protruding portion embedded in the first dielectric layer, wherein the first protruding portion extends from a bottom of the bottom portion to cover the first sidewall of the interconnect wiring; and a top portion embedded in the second dielectric layer. In some embodiments, the bottom portion includes a first bottom dimension and a first top dimension, the top portion includes a second bottom dimension and a second bottom dimension, the first top dimension is greater than the first bottom dimension, the second top dimension is greater than the second bottom dimension, and the second bottom dimension is greater than the first top dimension. In some embodiments, the semiconductor structure further includes a second protruding portion, wherein the second protruding portion extends from the bottom of the bottom portion to cover a second sidewall of the interconnect wiring, the second sidewall is opposite to the first sidewall, and the first protruding portion and the second protruding portion are located at opposite sides of the interconnect wiring. In some embodiments, the bonding conductor lands on a corner of the interconnect wiring, the first protruding portion further covers a second sidewall of the interconnect wiring, and the second sidewall abuts the first sidewall. In some embodiments, the bonding conductor lands on an end of the interconnect wiring, the first protruding portion further covers a second sidewall of the interconnect wiring and a third sidewall of the interconnect wiring, the second sidewall abuts the first sidewall, and the third sidewall is opposite to the first sidewall. In some embodiments, the bonding conductor includes a body portion embedded in the bonding dielectric structure; and a first protruding portion embedded in the bonding dielectric structure, wherein the protruding portion extends from a bottom of the body portion to cover the first sidewall of the interconnect wiring. In some embodiments, the bonding conductor further includes a second protruding portion, the second protruding portion extends from the bottom of the body portion to cover a second sidewall of the interconnect wiring, the second sidewall is opposite to the first sidewall, and the first protruding portion and the second protruding portion are located at opposite sides of the interconnect wiring. In some embodiments, the bonding conductor lands on a corner of the interconnect wiring, the first protruding portion further covers a second sidewall of the interconnect wiring, and the second sidewall abuts the first sidewall. In some embodiments, the bonding conductor lands on an end of the interconnect wiring, the first protruding portion further covers a second sidewall of the interconnect wiring and a third sidewall of the interconnect wiring, the second sidewall abuts the first sidewall, and the third sidewall is opposite to the first sidewall.

In accordance with some embodiments of the present disclosure, a semiconductor structure including semiconductor die and a bonding structure is provided. The semiconductor die includes an interconnect wiring of an interconnect structure. The bonding structure is disposed on and electrically connected to the interconnect structure. The bonding structure includes a bonding dielectric structure and a bonding conductor embedded in the bonding dielectric structure. The bonding dielectric structure is disposed on a top surface of the interconnect structure and covering the interconnect wiring. The bonding conductor lands on a top surface of the interconnect wiring and a first tapered sidewall of the interconnect wiring, the bonding dielectric structure is in contact with a second tapered sidewall of the interconnect wiring, the first tapered sidewall of the interconnect wiring extends from the top surface of the interconnect wiring to the second tapered sidewall of the interconnect wiring, and the second tapered sidewall of the interconnect wiring is steeper than the first tapered sidewall of the interconnect wiring. In some embodiments, the interconnect wiring further includes a tapered surface, the bonding conductor lands on the tapered surface, the tapered surface extends from the top surface of the interconnect wiring to the first tapered sidewall of the interconnect wiring, and the first tapered sidewall of the interconnect wiring is steeper than the tapered surface of the interconnect wiring. In some embodiments, the bonding conductor includes a body portion embedded in the bonding dielectric structure; and a first protruding portion embedded in the bonding dielectric structure, wherein the protruding portion extends from a bottom of the body portion to cover the first tapered sidewall of the interconnect wiring. In some embodiments, the bonding conductor further includes a second protruding portion, the second protruding portion extends from the bottom of the body portion to cover a third tapered sidewall of the interconnect wiring, the third tapered sidewall is opposite to the first tapered sidewall, and the first protruding portion and the second protruding portion are located at opposite sides of the interconnect wiring. In some embodiments, the bonding conductor lands on a corner of the interconnect wiring, the first protruding portion further covers a third tapered sidewall of the interconnect wiring, and the third tapered sidewall abuts the first tapered sidewall. In some embodiments, the bonding conductor lands on an end of the interconnect wiring, the first protruding portion further covers a third tapered sidewall of the interconnect wiring and a fourth tapered sidewall of the interconnect wiring, the third tapered sidewall abuts the first tapered sidewall, and the fourth tapered sidewall is opposite to the first tapered sidewall.

In accordance with some embodiments of the present disclosure, a semiconductor structure including a semiconductor die and a bonding structure is provided. The semiconductor die includes an interconnect wiring. The bonding structure is disposed on and electrically connected to the interconnect wiring. The bonding structure includes a bonding dielectric structure disposed on the top surface of the semiconductor die and covering the interconnect wiring; and a bonding conductor embedded in the bonding dielectric structure, wherein the bonding conductor lands on a top surface of the interconnect wiring, and the bonding conductor includes a first protruding portion laterally covered a first sidewall of the interconnect wiring. In some embodiments, the bonding conductor further includes a second protruding portion, the second protruding portion laterally covered a second sidewall of the interconnect wiring, the second sidewall is opposite to the first sidewall, and the first protruding portion and the second protruding portion are located at opposite sides of the interconnect wiring. In some embodiments, the bonding conductor lands on a corner or an end of the interconnect wiring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor substrate;
an interconnect structure disposed on the semiconductor substrate, the interconnect structure comprising an interconnect wiring distributed on a top surface of the interconnect structure;
a bonding structure disposed on and electrically connected to the interconnect structure, the bonding structure comprising:
a bonding dielectric structure disposed on the top surface of the interconnect structure and covering the interconnect wiring; and
a bonding conductor embedded in the bonding dielectric structure, wherein the bonding conductor lands on a top surface of the interconnect wiring and a first sidewall of the interconnect wiring, wherein the top surface of the interconnect wiring comprises a recessed portion covered by the bonding conductor, the bonding conductor comprises a body portion and a first protruding portion, the body portion and the first protruding portion are embedded in the bonding dielectric structure, the first protruding portion extends from a bottom of the body portion toward the interconnect structure such that first protruding portion is in contact with the first sidewall of the interconnect wiring and located at a position lower than the recessed portion, and the recessed portion abuts the first sidewall of the interconnect wiring.

2. The semiconductor structure of claim 1, wherein the bonding dielectric structure comprises:
a first dielectric layer disposed on the top surface of the interconnect structure and covering the interconnect wiring;
a second dielectric layer disposed over the first dielectric layer; and
an etch stop layer disposed between the first dielectric layer and the second dielectric layer, wherein the bonding conductor penetrates through the first dielectric layer, the etch stop layer and the second dielectric layer.

3. The semiconductor structure of claim 2, wherein the body portion comprises a bottom portion and a top portion, the bottom portion is embedded in the first dielectric layer and the etch stop layer, and the top portion is embedded in the second dielectric layer.

4. The semiconductor structure of claim 3, wherein the bottom portion comprises a first bottom dimension and a first top dimension, the top portion comprises a second top dimension and a second bottom dimension, the first top dimension is greater than the first bottom dimension, the second top dimension is greater than the second bottom dimension, and the second bottom dimension is greater than the first top dimension.

5. The semiconductor structure of claim 3 further comprising a second protruding portion, wherein the second protruding portion extends from the bottom of the bottom portion to cover a second sidewall of the interconnect wiring, the second sidewall is opposite to the first sidewall, and the first protruding portion and the second protruding portion are located at opposite sides of the interconnect wiring.

6. The semiconductor structure of claim 3, wherein the bonding conductor lands on a corner of the interconnect wiring, the first protruding portion further covers a second sidewall of the interconnect wiring, and the second sidewall abuts the first sidewall.

7. The semiconductor structure of claim 3, wherein the bonding conductor lands on an end of the interconnect wiring, the first protruding portion further covers a second sidewall of the interconnect wiring and a third sidewall of the interconnect wiring, the second sidewall abuts the first sidewall, and the third sidewall is opposite to the first sidewall.

8. The semiconductor structure of claim 1, wherein the bottom portion is in contact with the recessed portion of the interconnect wiring.

9. A semiconductor structure, comprising:
a semiconductor die comprising an interconnect wiring of an interconnect structure;
a bonding structure disposed on and electrically connected to the interconnect structure, the bonding structure comprising:
a bonding dielectric structure disposed on a top surface of the interconnect structure and covering the interconnect wiring; and
a bonding conductor embedded in the bonding dielectric structure, wherein the bonding conductor lands on a top surface of the interconnect wiring and a first tapered sidewall of the interconnect wiring, the top surface of the interconnect structure comprises a recessed portion covered by the bonding conductor, the recessed portion abuts the first tapered sidewall, and the bonding conductor comprises a protruding portion located at a position lower than the recessed portion.

10. The semiconductor structure of claim 9, wherein the bonding dielectric structure is in contact with a second tapered sidewall of the interconnect wiring.

11. The semiconductor structure of claim 10, wherein the first tapered sidewall of the interconnect wiring extends from the top surface of the interconnect wiring to the second tapered sidewall of the interconnect wiring.

12. The semiconductor structure of claim 11, wherein the second tapered sidewall of the interconnect wiring is steeper than the first tapered sidewall of the interconnect wiring.

13. The semiconductor structure of claim 9, wherein the interconnect wiring further comprises a tapered surface, the bonding conductor lands on the tapered surface, the tapered surface extends from the top surface of the interconnect wiring to the first tapered sidewall of the interconnect wiring, and the first tapered sidewall of the interconnect wiring is steeper than the tapered surface of the interconnect wiring.

14. The semiconductor structure of claim 9, wherein the bonding conductor comprises:
a body portion embedded in the bonding dielectric structure; and
a first protruding portion embedded in the bonding dielectric structure, wherein the protruding portion extends from a bottom of the body portion to cover the first tapered sidewall of the interconnect wiring.

15. The semiconductor structure of claim 14, wherein the bonding conductor further comprises a second protruding portion, the second protruding portion extends from the bottom of the body portion to cover a third tapered sidewall of the interconnect wiring, the third tapered sidewall is opposite to the first tapered sidewall, and the first protruding portion and the second protruding portion are located at opposite sides of the interconnect wiring.

16. The semiconductor structure of claim 14, wherein the bonding conductor lands on a corner of the interconnect wiring, the first protruding portion further covers a third tapered sidewall of the interconnect wiring, and the third tapered sidewall abuts the first tapered sidewall.

17. The semiconductor structure of claim 14, wherein the bonding conductor lands on an end of the interconnect wiring, the first protruding portion further covers a third tapered sidewall of the interconnect wiring and a fourth tapered sidewall of the interconnect wiring, the third tapered sidewall abuts the first tapered sidewall, and the fourth tapered sidewall is opposite to the first tapered sidewall.

18. A semiconductor structure, comprising:
a semiconductor die comprising an interconnect wiring;
a bonding structure disposed on and electrically connected to the interconnect wiring, the bonding structure comprising:
a bonding dielectric structure disposed on a top surface of the semiconductor die and covering the interconnect wiring; and
a bonding conductor embedded in the bonding dielectric structure, wherein the top surface of the interconnect structure comprises a recessed portion covered by and in contact with the bonding conductor, and the bonding conductor comprises a first protruding portion located at a position lower than the recessed portion, the first protruding portion is in contact with a first sidewall of the interconnect wiring, and the recessed portion abuts the first sidewall of the interconnect wiring.

19. The semiconductor structure of claim 18, wherein the bonding conductor further comprises a second protruding portion, the second protruding portion laterally covered a second sidewall of the interconnect wiring, the second sidewall is opposite to the first sidewall, and the first protruding portion and the second protruding portion are located at opposite sides of the interconnect wiring.

20. The semiconductor structure of claim 18, wherein the bonding conductor lands on a corner or an end of the interconnect wiring.
